(19) United States
(12) Patent Application Publication
(10) Pub. No.: US 2025/0087771 A1
(43) Pub. Date: Mar. 13, 2025

(54) ACCESS PORTS FOR FACILITATING BATTERY ARRAY INTERNAL MEASUREMENTS

(71) Applicant: FORD GLOBAL TECHNOLOGIES, LLC, Dearborn, MI (US)

(72) Inventors: Francisco FERNANDEZ-GALINDO, Canton, MI (US); Daniel Paul ROBERTS, Livonia, MI (US); Liam E. WEST, Ferndale, MI (US)

(21) Appl. No.: 18/465,498

(22) Filed: Sep. 12, 2023

(51) Int. Cl. H01M 10/42; G01R 31/382; H01M 50/211; H01M 50/231; H01M 50/507; H01M 50/522; H01M 50/569; H01M 50/588; H01M 50/593

(52) U.S. Cl. CPC H01M 10/4285; G01R 31/382; H01M 50/211; H01M 50/231; H01M 50/507; H01M 50/522; H01M 50/569; H01M 50/588; H01M 50/593; H01M 2220/20

(57) ABSTRACT

Battery arrays are provided for traction battery packs. An exemplary battery array may include one or more access ports for guiding a measurement probe of a testing device directly to an internal component (e.g., a bus bar) of the battery array. The testing device may then be utilized to measure a property (e.g., voltage, resistance, current, temperature, etc.) associated with the internal component without the need to first disassemble the battery array.

### TECHNICAL FIELD

This disclosure relates generally to traction battery packs, and more particularly to battery arrays that include one or more access ports for facilitating the measurement of one or more internal battery cell/battery array properties.

### BACKGROUND

Electrified vehicles include a traction battery pack for powering electric machines and other electrical loads of the vehicle. The traction battery pack includes a plurality of battery cells and various other battery internal components that support electric vehicle propulsion.

### SUMMARY

A battery array for a traction battery pack according to an exemplary aspect of the present disclosure includes, among other things, an array housing, an internal component arranged inside of the array housing, and an access port formed through a plate member of the array housing and configured to provide direct access for measuring a property associated with the internal component.

In a further non-limiting embodiment of the foregoing battery array, the access port extends through the plate member and further through an insulation layer that is arranged between the plate member and the internal component.

In a further non-limiting embodiment of either of the foregoing battery arrays, the internal component is a bus bar.

In a further non-limiting embodiment of any of the foregoing battery arrays, the bus bar is held within a bus bar frame of a bus bar module.

In a further non-limiting embodiment of any of the foregoing battery arrays, the bus bar electrically connects a plurality of battery cells of the battery array.

In a further non-limiting embodiment of any of the foregoing battery arrays, the bus bar module further includes a battery pack sensing module that is operably connected to a sense lead associated with the plurality of battery cells.

In a further non-limiting embodiment of any of the foregoing battery arrays, the bus bar module and the battery pack sensing module are covered by the plate member.

In a further non-limiting embodiment of any of the foregoing battery arrays, an insulator is attached to the plate member and arranged to circumscribe the access port.

In a further non-limiting embodiment of any of the foregoing battery arrays, the access port is sized and shaped to receive a measurement probe of a testing device that is configured to measure the property.

In a further non-limiting embodiment of any of the foregoing battery arrays, the property is a voltage, resistance, current, or temperature of the internal component.

A battery array for a traction battery pack according to another exemplary aspect of the present disclosure includes, among other things, a plurality of battery cells, a bus bar module including a bus bar for electrically connecting the plurality of battery cells, an array housing including a plate member arranged to cover the bus bar module, and an access port formed through the plate member and configured to guide a measurement probe to the bus bar.

In a further non-limiting embodiment of the foregoing battery array, the access port extends through the plate member and further through an insulation layer that is arranged between the plate member and the bus bar module.

In a further non-limiting embodiment of either of the foregoing battery arrays, the bus bar is held within a bus bar frame of the bus bar module.

In a further non-limiting embodiment of any of the foregoing battery arrays, the bus bar is a metallic component, and the bus bar frame is a plastic component.

In a further non-limiting embodiment of any of the foregoing The battery arrays, the bus bar module further includes a battery pack sensing module that is operably connected to a sense lead associated with the plurality of battery cells.

In a further non-limiting embodiment of any of the foregoing The battery arrays, the bus bar module and the battery pack sensing module are covered by the plate member.

In a further non-limiting embodiment of any of the foregoing The battery arrays, an insulator is attached to the plate member and arranged to circumscribe the access port.

In a further non-limiting embodiment of any of the foregoing The battery arrays, the insulator is made of a non-conductive material.

In a further non-limiting embodiment of any of the foregoing battery arrays, the measurement probe is operably connected to a testing device.

In a further non-limiting embodiment of any of the foregoing The battery arrays, the testing device is a multimeter.

The embodiments, examples, and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates an electrified vehicle.

FIG. 2 illustrates a battery array of a traction battery pack.

FIG. 3 illustrates the battery array of FIG. 2 with portions of an array housing removed for better illustrating select internal components of the battery array.

FIG. 4 is a cross-sectional view through section 4-4 of FIG. 2. The inset of FIG. 4 schematically illustrates the measurement of a property associated with an internal component of the battery array.

FIG. 5 schematically illustrates an exemplary access port of a battery array.

### DETAILED DESCRIPTION

This disclosure details battery arrays for traction battery packs. An exemplary battery array may include one or more access ports for guiding a measurement probe of a testing device directly to an internal component (e.g., a bus bar) of the battery array. The testing device may then be utilized to measure a property (e.g., voltage, resistance, current, temperature, etc.) associated with the internal component without the need to first disassemble the battery array. These and other features are discussed in greater detail in the following paragraphs of this detailed description.

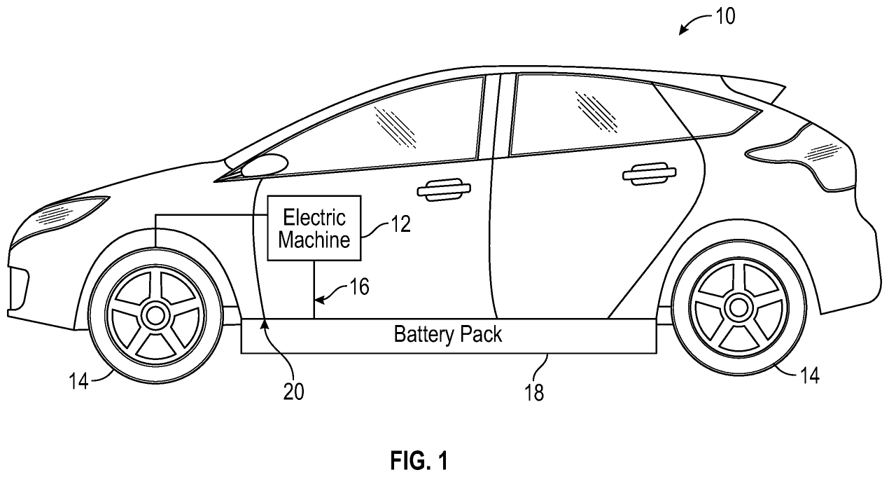

FIG. 1 schematically illustrates an electrified vehicle 10. The electrified vehicle 10 may include any type of electrified powertrain. In an embodiment, the electrified vehicle 10 is a battery electric vehicle (BEV). However, the concepts described herein are not limited to BEVs and could extend to other electrified vehicles, including, but not limited to, hybrid electric vehicles (HEVs), plug-in hybrid electric vehicles (PHEV's), fuel cell vehicles, etc. Therefore, although not specifically shown in the exemplary embodiment, the powertrain of the electrified vehicle 10 could be equipped with an internal combustion engine that can be employed either alone or in combination with other power sources to propel the electrified vehicle 10.

In the illustrated embodiment, the electrified vehicle 10 is depicted as a car. However, the electrified vehicle 10 could alternatively be a sport utility vehicle (SUV), a van, a pickup truck, or any other vehicle configuration. Although a specific component relationship is illustrated in the figures of this disclosure, the illustrations are not intended to limit this disclosure. The placement and orientation of the various components of the electrified vehicle 10 are shown schematically and could vary within the scope of this disclosure. In addition, the various figures accompanying this disclosure are not necessarily drawn to scale, and some features may be exaggerated or minimized to emphasize certain details of a particular component or system.

In an embodiment, the electrified vehicle 10 is a full electric vehicle propelled solely through electric power, such as by one or more electric machines 12, without any assistance from an internal combustion engine. The electric machine 12 may operate as an electric motor, an electric generator, or both. The electric machine 12 receives electrical power and can convert the electrical power to torque for driving one or more wheels 14 of the electrified vehicle 10.

A voltage bus 16 may electrically couple the electric machine 12 to a traction battery pack 18. The traction battery pack 18 is an exemplary electrified vehicle battery. The traction battery pack 18 may be a high voltage traction battery pack assembly that includes a plurality of battery cell groupings capable of outputting electrical power to power the electric machine 12 and/or other electrical loads of the electrified vehicle 10. Other types of energy storage devices and/or output devices could alternatively or additionally be used to electrically power the electrified vehicle 10.

The traction battery pack 18 may be secured to an underbody 20 of the electrified vehicle 10. However, the traction battery pack 18 could be located elsewhere on the electrified vehicle 10 within the scope of this disclosure.

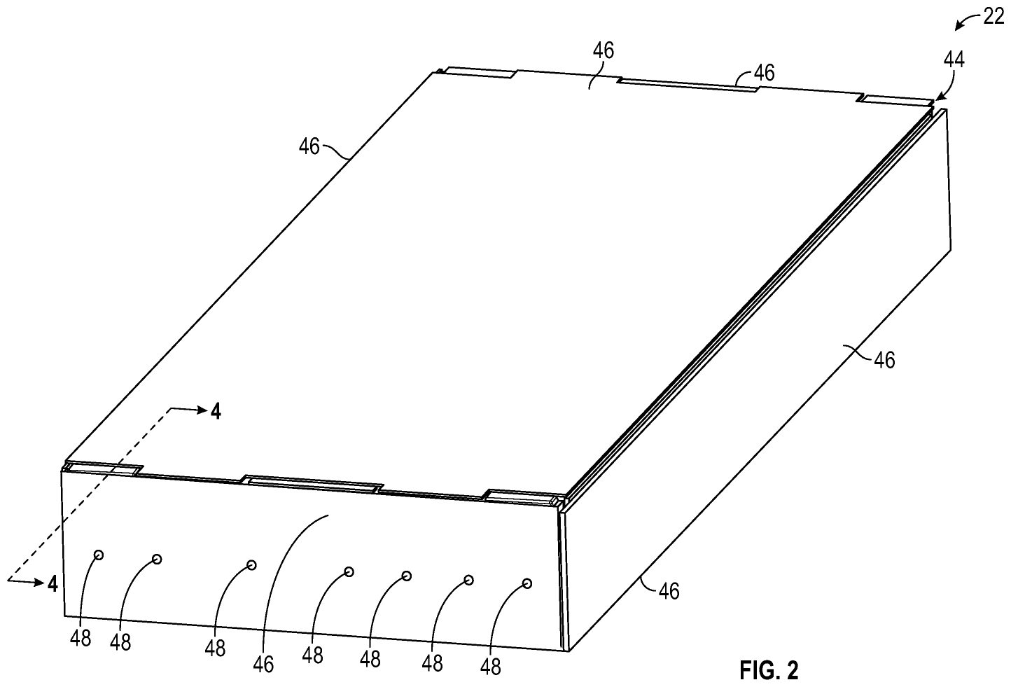

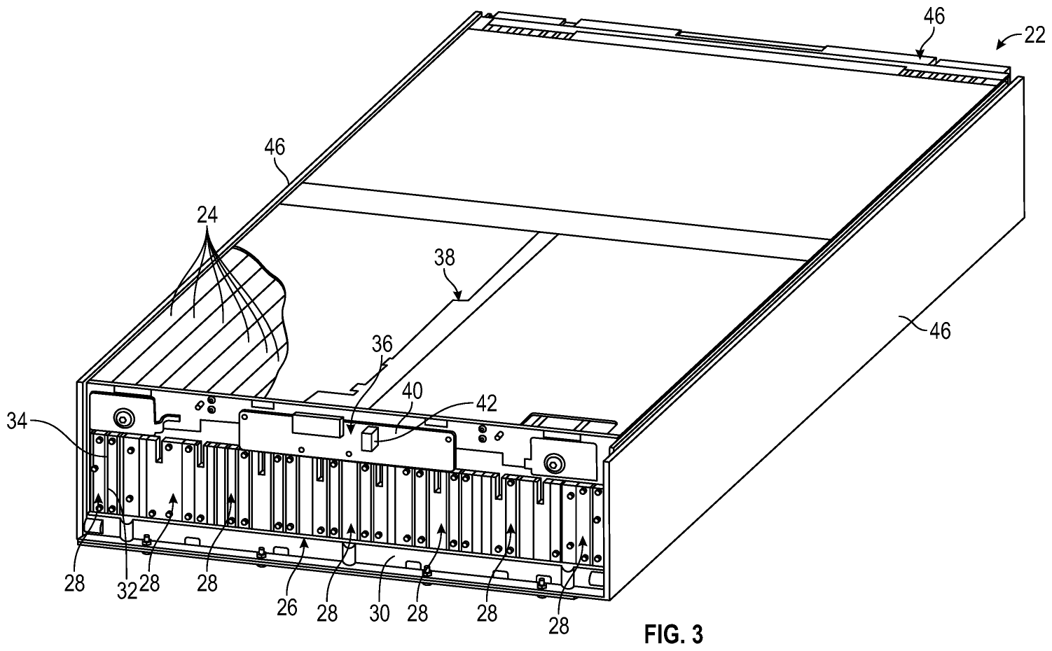

FIGS. 2 and 3 illustrate an exemplary battery array 22 for a traction battery pack, such as the traction battery pack 18 of FIG. 1, for example. One or more battery arrays having a design similar to the battery array 22 shown in FIGS. 2-3 could be packaged within the traction battery pack 18. As explained in further detail below, the battery array 22 may incorporate features designed for facilitating the measurement of one or more properties associated with internal components of the battery array 22 without the need to first disassemble the battery array 22.

The battery array 22 may include a plurality of battery cells 24 (best seen in cutaway portion of FIG. 3). In an embodiment, the battery cells 24 are lithium-ion pouch cells. However, battery cells having other geometries (cylindrical, prismatic, etc.) and/or chemistries (nickel-metal hydride, lead-acid, etc.) could alternatively be utilized within the scope of this disclosure. The total number of battery cells 24 provided within the battery array 22 may vary and is not intended to limit this disclosure.

The battery cells 24 may be stacked side-by-side along a stack axis to construct a grouping of battery cells 24, sometimes referred to as a “cell stack.” The cell stack may be grouped into two or more cell banks, although the exact configuration of the cell stack of battery cells 24 is not intended to limit this disclosure.

The battery array 22 may additionally include one or more bus bar modules 26 for electrically connecting the battery cells 24 of the cell stack. The bus bar module 26 may include a plurality of bus bars 28 held within a bus bar frame 30. The total number of bus bars 28 is not intended to limit this disclosure. Further, at least one of the bus bars 28 could be sized differently than the other bus bars 28 of the bus bar module 26.

The bus bars 28 of the bus bar module 26 may be joined to tab terminals 32 of the battery cells 24 for electrically connecting the battery cells 24 of the battery array 22 to one another. Once electrically coupled, the battery cells 24 may supply electrical power necessary for achieving electric propulsion of the electrified vehicle 10.

Each bus bar 28 may include openings 34 that are each sized for receiving one of the cell tab terminals 32. The cell tab terminals 32 may extend through the openings 34 such that at least a portion of each cell tab terminal 32 is located on an opposite side of the bus bar 28 from its respective battery cell 24.

The bus bars 28 may be metallic components of the bus bar module 26, and the bus bar frame 30 may be a plastic component of the bus bar module 26. In an embodiment, the bus bars 28 are made of copper or aluminum, and the bus bar frame 30 is made of polypropylene or polyethylene. However, other materials are contemplated within the scope of this disclosure.

The bus bar module 26 may additionally include a battery pack sensing module (BPSM) 36. The BPSM 36 may include circuitry that connects to sense leads 38 of the battery array 22. The BPSM 36 may include, among other things, a circuit board assembly 40 and a daisychain connector 42. Data from the sense leads 38, such as data indicating temperature and voltage information associated with the battery cells 24, for example, may be communicated to the circuit board assembly 40. The circuit board assembly 40 may be configured to read analog signal data and covert the data to a digital data stream. This digital data stream can be communicated, such as via the daisychain connector 42, to a controller (e.g., a battery energy control module (not shown)) that is programmed to monitor and control operations of the battery array 22. Since data from the BPSM 36 is only available digitally, it is typically necessary to disassemble the battery array 22 in order to access certain measuring points for making direct measurements.

The battery cells 24, the bus bar module(s) 26, and various outer internal components of the battery array 22 may be housed within an array housing 44. The array housing 44 may be arranged to substantially surround the cell stack of battery cells 24, for example. The array housing 44 may include a plurality of plate members 46. In an embodiment, the plate members 46 may be arranged to provide a top cover, a bottom cover, a pair of side covers, and a pair of end covers of the battery array 22. However, other configurations of the array housing 44 are contemplated within the scope of this disclosure. The BPSM 36 may be mounted either internally or externally relative to the array housing 44.

The battery array 22 may periodically require testing, such as for diagnosing electrical issues (e.g., an electrical isolation, etc.) or for initial end-of-line testing of the battery array 22, for example. In prior battery array implementations, this type of testing/diagnosis could not be performed without first disassembling portions of the battery array 22 (e.g., such as by removing portions of the array housing 44), which can be inconvenient, time consuming, and labor intensive for technicians. In some cases, it may not be possible to disassemble the battery array 22 due to welded or other permanent connections. The battery array 22 may therefore include one or more access ports 48 that are designed to provide access to internal components of the battery array 22 for performing tests/diagnostics without the need to disassemble the array housing 44 of any other component of the battery array 22.

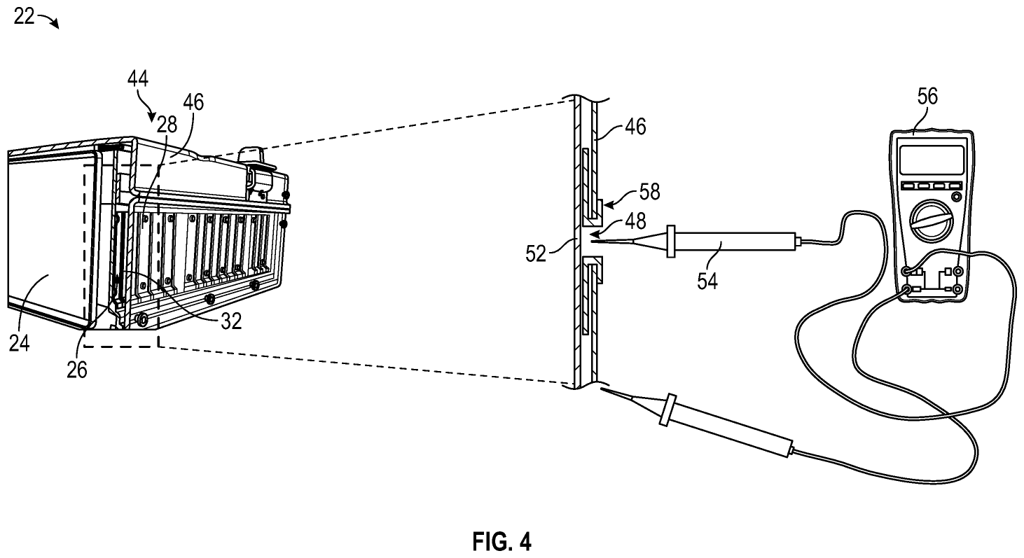

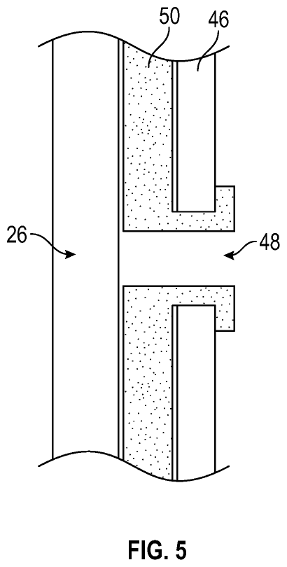

The access ports 48 may be formed through one or more of the plate members 46 of the array housing 44 (see, e.g., FIGS. 2 and 4). The access ports 48 may additionally be formed through one or more insulation layers 50 that are arranged between the bus bar module 26 and the plate member 46 of the array housing 44 that is arranged to cover the bus bar module 26 (sec., e.g., FIG. 5).

Referring now primarily to FIG. 4, each access port 48 may be arranged to provide direct access to an internal component 52 of the battery array 22. The internal component 52 could be one of the bus bars 28 or another internal component of the battery array 22. Each access port 48 may be sized and shaped to guide a measurement probe 54 of a testing device 56 to the internal component 52 while also preventing finger access by the technician. The measurement probe 54 may be received in direct contact with the internal component 52 once inserted into and through the access port 48. Once positive contact between the measurement probe 54 and the internal component 52 has been achieved, the testing device 56 may be operated to measure one or more properties (e.g., voltage, resistance, current, temperature, etc.) associated with the internal component 52.

The measurement probe 54 may be operably connected to the testing device 56. The testing device 56 may be a multimeter, for example. However, other types of testing devices could be utilized within the scope of this disclosure.

Each access port 48 may be lined with an insulator 58 to prevent electrical shorts to the plate member 46 of the array housing 44. The insulator 58 may be secured to the respective plate member 46 and may be arranged to circumscribe the access port 48. Each insulator 58 may be made of a non-conductive material, such as a polymeric material, for example.

The exemplary battery arrays of this disclosure include one or more access ports for guiding probes to a desired internal position of the array, thereby facilitating electrical property and temperature measurements without the need to first disassemble the battery array. The access ports provide for faster troubleshooting, accurate root cause analysis, simpler instrumentation during assembly, and the ability to perform multiple diagnostics on specific cell banks, sense leads, and/or high voltage component areas of the battery array.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. A battery array for a traction battery pack, comprising:
an array housing;
an internal component arranged inside of the array housing; and
an access port formed through a plate member of the array housing and configured to provide direct access for measuring a property associated with the internal component.

2. The battery array as recited in claim 1, wherein the access port extends through the plate member and further through an insulation layer that is arranged between the plate member and the internal component.

3. The battery array as recited in claim 1, wherein the internal component is a bus bar.

4. The battery array as recited in claim 3, wherein the bus bar is held within a bus bar frame of a bus bar module.

5. The battery array as recited in claim 4, wherein the bus bar electrically connects a plurality of battery cells of the battery array.

6. The battery array as recited in claim 5, wherein the bus bar module further includes a battery pack sensing module that is operably connected to a sense lead associated with the plurality of battery cells.

7. The battery array as recited in claim 6, wherein the bus bar module and the battery pack sensing module are covered by the plate member.

8. The battery array as recited in claim 1, comprising an insulator that is attached to the plate member and arranged to circumscribe the access port.

9. The battery array as recited in claim 1, wherein the access port is sized and shaped to receive a measurement probe of a testing device that is configured to measure the property.

10. The battery array as recited in claim 1, wherein the property is a voltage, resistance, current, or temperature of the internal component.

11. A battery array for a traction battery pack, comprising:
a plurality of battery cells;
a bus bar module including a bus bar for electrically connecting the plurality of battery cells;
an array housing including a plate member arranged to cover the bus bar module; and
an access port formed through the plate member and configured to guide a measurement probe to the bus bar.

12. The battery array as recited in claim 11, wherein the access port extends through the plate member and further through an insulation layer that is arranged between the plate member and the bus bar module.

13. The battery array as recited in claim 11, wherein the bus bar is held within a bus bar frame of the bus bar module.

14. The battery array as recited in claim 13, wherein the bus bar is a metallic component, and the bus bar frame is a plastic component.

15. The battery array as recited in claim 11, wherein the bus bar module further includes a battery pack sensing module that is operably connected to a sense lead associated with the plurality of battery cells.

16. The battery array as recited in claim 15, wherein the bus bar module and the battery pack sensing module are covered by the plate member.

17. The battery array as recited in claim 11, comprising an insulator that is attached to the plate member and arranged to circumscribe the access port.

18. The battery array as recited in claim 17, wherein the insulator is comprised of a non-conductive material.

19. The battery array as recited in claim 11, wherein the measurement probe is operably connected to a testing device.

20. The battery array as recited in claim 19, wherein the testing device is a multimeter.
